(19) United States
(12) Patent Application Publication
(10) Pub. No.: US 2017/0278925 A1
(43) Pub. Date: Sep. 28, 2017

(54) INTRODUCING MATERIAL WITH A LOWER ETCH RATE TO FORM A T-SHAPED SDB STI STRUCTURE

(71) Applicant: GLOBALFOUNDRIES Inc., Grand Cayman (KY)

(72) Inventors: Jianwei PENG, Albany, NY (US); Xusheng WU, Ballston Lake, NY (US)

(21) Appl. No.: 15/078,247

(22) Filed: Mar. 23, 2016

(51) Int. Cl. H01L 29/06; H01L 29/66; H01L 21/3105; H01L 29/78; H01L 21/308; H01L 21/306

(52) U.S. Cl. CPC H01L 29/0649; H01L 21/3085; H01L 21/30604; H01L 21/3105; H01L 29/785; H01L 29/66795

(57) ABSTRACT

A method of introducing SDB material with a lower etch rate during a formation of a t-shape SDB STI structure are provided. Embodiments include providing an STI region in a Si substrate; forming a hardmask over the STI region and the Si substrate; forming a cavity through the hardmask over the STI region, the cavity having a width greater than a width of the STI region; depositing a SDB material in the cavity with an etch rate lower than HDP oxide to form a t-shaped SDB STI structure; and removing the hardmask.

### TECHNICAL FIELD

The present disclosure relates to fabrication of semiconductor devices including a single diffusion break (SDB). The present disclosure is particularly applicable to the fabrication of a t-shaped SDB STI structure for the 14 nanometer (nm) technology node and beyond.

### BACKGROUND

Isolation structures are used during fabrication of semiconductor to isolate numerous materials placed on a semiconductor substrate. Among these isolation structures, shallow trench isolation (STI) structures are employed because the resulting trench can be well adapted for the small device isolation area. The STI region is formed by etching a shallow trench in a silicon (Si) substrate and thereafter filling the trench with a dielectric material (e.g., oxide). Similarly, an SDB is a technique for technology scaling to achieve the same functional integrated circuits on a smaller design area. An SDB can be used to reduce the circuit area to enable the formation of high-density integrated circuits. The SDB is formed by making the STI region t-shaped using a high density plasma (HDP) oxide over the STI region. However, the current SDB process has a severe facet embedded silicon germanium (eSiGe) and silicon phosphorus (eSiP) issue due to the limited Si remaining on SDB STI sidewalls after source/drain (S/D) cavity formation adjacent to the STI region.

A need therefore exists for methodology enabling protection of the Si on the SDB STI sidewalls during the PFET cavity etch and the resulting device.

### SUMMARY

An aspect of the present disclosure is a method including utilization of an SDB material having a lower etch rate than HDP oxide.

Another aspect of the present disclosure is a device including an SDB material that prevents S/D cavities from touching the STI.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing an STI region in a Si substrate; forming a hardmask over the STI region and the Si substrate; forming a cavity through the hardmask over the STI region, the cavity having a width greater than a width of the STI region; depositing an SDB material in the cavity with an etch rate lower than HDP oxide to form a t-shape SDB STI structure; and removing the hardmask.

Another aspect includes forming the SDB material of silicon dioxide (SiO₂) modified with nitrogen (N). Other aspects include the SDB material having an etch rate ratio between etch rates of pure oxide and silicon nitride (SiN). A further aspect includes modifying the SiO₂ with 10 to 40% of N. Another aspect includes forming the SDB material of SiO₂ modified with carbon (C). A further aspect includes the SDB material having an etch rate ratio between etch rates of pure oxide and silicon carbide (SiC). A further aspect includes modifying the SiO₂ with 1 to 15% of C.

A further aspect includes providing trenches filled with STI material in the Si substrate perpendicular to the STI region; recessing the STI material to form Si FINs subsequent to removing the hardmask, wherein an SDB width is greater than the STI region width subsequent to recessing the STI material. Other aspects include the SDB layer having a width of 35 nm to 90 nanometers (nm).

Another aspect includes forming a cavity in the Si substrate adjacent to each side of the STI; and epitaxially growing an eSiGe/eSiP in the cavities. Other aspects include the SDB layer preventing the cavity from touching the STI.

A further aspect of the present disclosure is a device including: a Si substrate with FINs; STI material in the substrate between the FINs; an STI region in a FIN and extending into the underlaying Si substrate; an SDB material with an etch rate lower than HDP oxide over the STI forming a t-shape SDB STI structure; and source/drain (S/D) regions on opposite sides of the STI region, the S/D being separated from the STI region with silicon.

Aspects of the device include the SDB layer having a width of 35 nm to 90 nm. Other aspects include the SDB including SiO₂ modified with N, and the SDB having an etch rate ratio between etch rates of pure oxide and SiN.

A further aspect includes the SiO₂ being modified with 10 to 40% of N. A further aspect includes the SDB including SiO₂modified with C, and the SDB material having an etch rate ratio between etch rates of pure oxide and SiC. A further aspect includes the SiO₂ being modified with 1 to 15% of C. Another aspect includes the SDB material including pure nitride.

Another aspect of the present disclosure is a method including: providing an STI region in a Si substrate; depositing a hardmask silicon nitride (HM SiN) material over the STI region and the Si substrate to form a hardmask; forming a photoresist on an upper surface of the hardmask; removing a center portion of the hardmask to form an opening; removing the photoresist; etching the STI region and the Si substrate through the opening to form a cavity over the STI region, the cavity having a width greater than a width of the STI region; depositing a SDB material including SDB material of SiO₂modified with N and C or pure nitride, in the cavity; planarizing the SDB material down to the hardmask to form a t-shape SDB STI structure; and removing the hardmask; providing trenches filled with STI material in the Si substrate perpendicular to the STI region; recessing the STI material to form Si FINs subsequent to removing the hardmask.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A through 1G schematically illustrate sequential steps of a process for forming a t-shaped SDB STI structure with an SDB material having an etch rate lower than HDP oxide, in accordance with an exemplary embodiment; and

FIG. 2A through 2B schematically illustrate SDB material preventing S/D cavities from touching STI sidewalls, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of severe facet epitaxial (EPI) growth attendant upon forming SDBs using HDP oxide. In accordance with embodiments of the present disclosure, a t-shape SDB STI structure is achieved by replacing the HDP oxide with an SDB material having a significantly lower etch rate. Since the SDB material has a slower etch rate, the remaining SDB material has a larger lateral width and be able to protect the Si on the STI sidewalls during the S/D cavity etch, which in turn provides a more symmetric seed layer for subsequent S/D Epitaxy growth.

Methodology in accordance with embodiments of the present disclosure includes providing an STI region in a Si substrate and forming a hardmask over the STI region and the Si substrate. Then, a cavity having a width greater than a width of the STI region is formed through the hardmask over the STI region. Next, an SDB material with an etch rate lower than HDP oxide is deposited in the cavity to form a t-shape SDB STI structure. Then, the hardmask is removed.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

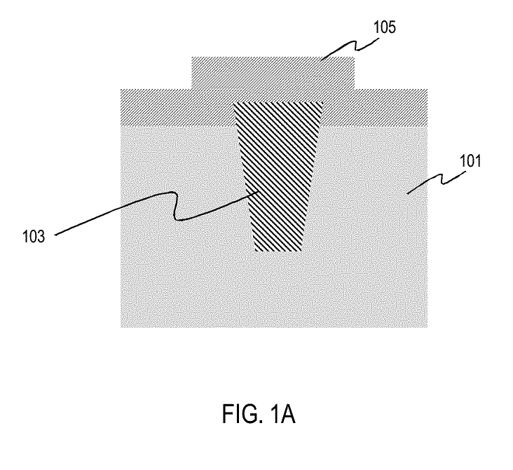

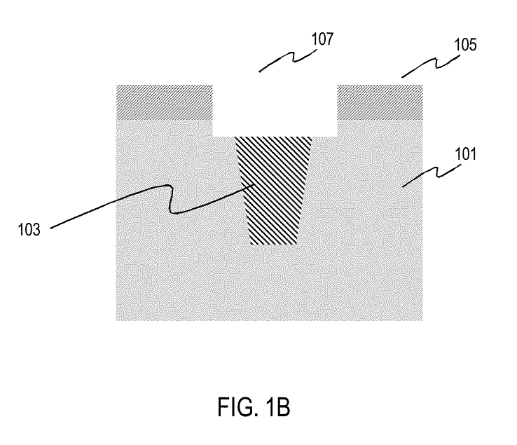

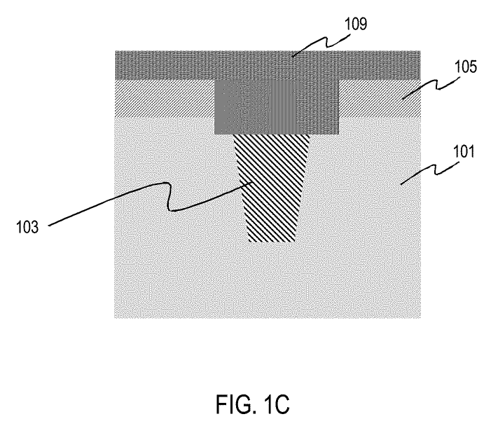

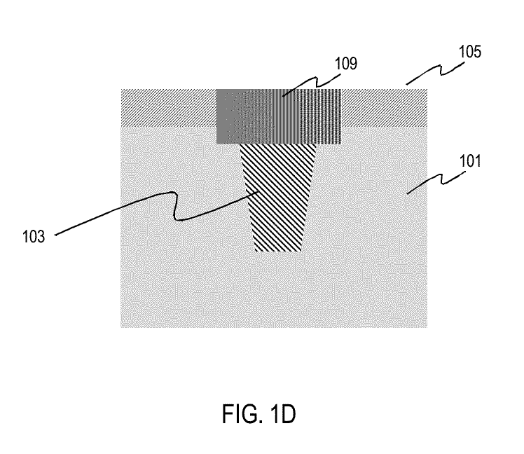

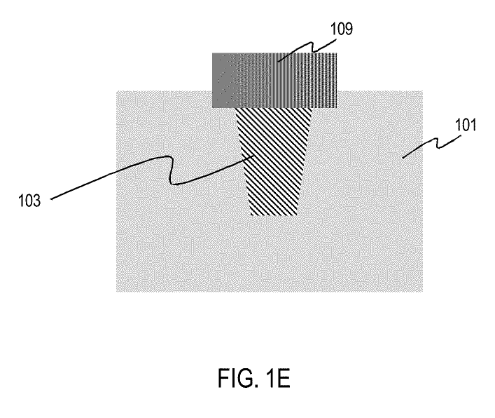

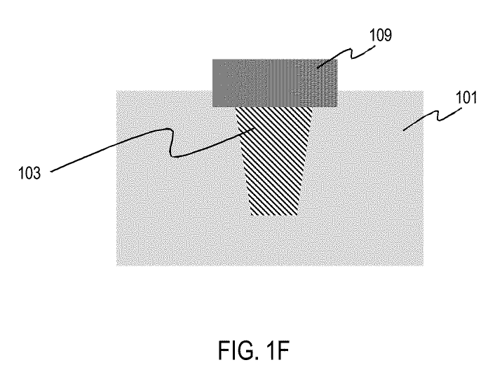

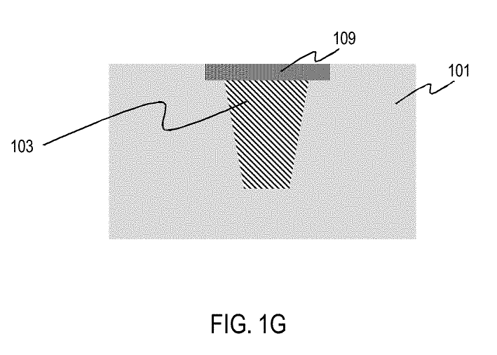

FIG. 1A through 1G schematically illustrate sequential steps of a process for forming a t-shaped SDB STI structure with an SDB material having an etch rate lower than HDP oxide, in accordance with an exemplary embodiment. Adverting to FIG. 1A, a silicon substrate includes alternating silicon portions (including silicon portion 101) and STI portions (not shown for illustrative convenience) on the silicon substrate. An STI region 103, e.g., formed of SiO₂, is formed perpendicular to and embedded in the Si portions 101 and the STI portions, and FIG. 1A illustrates a cross-sectional view along the length of one Si portion 101. A hardmask 105, e.g., formed of silicon nitride (SiN), is then formed over the Si portion 101 and the STI region 103. In FIG. 1B, a photoresist (not shown for illustrative convenience) is formed on the upper surface of the hardmask 105. Then, an opening, for example with a width of 35 nm to 90 nm, is formed in the hardmask 105 centered over the STI region 103. Subsequently, the photoresist is removed. Then, the Si portion 101 and the STI region 103 are etched through the opening to form a cavity 107 over the STI region 103. The cavity 107 has a width greater than the width of the STI region.

In FIG. 1C, an SDB material 109 is deposited over the hardmask 105 and the cavity 107. The SDB may be formed of SiO₂modified with 10 to 40% of N, where the SDB material has an etch rate ratio between etch rates of pure oxide and SiN. Alternatively, the SDB may be formed of SiO₂modified with 1 to 15% of C, where the SDB material has an etch rate ratio between etch rates of pure oxide and SiC. The SDB material 109 may also be formed of pure nitrogen. Then, the SDB material 109 is planarized, e.g., by chemical mechanical polishing (CMP), down to the hardmask 105, as depicted in FIG. 1D. Thereafter, the hardmask 105 is removed and a resulting t-shaped SDB STI structure is formed, as depicted in FIG. 1E.

Adverting to FIGS. 1F and 1G, subsequent to removing the hardmask 105 the STI regions that are not shown are recessed to form Si FINs (at the silicon portions 1E). The STI material is recessed by a dry etch (FIG. 1F), e.g. using a radial line slot antenna (RLSA) tool for etching, followed by a wet etch (FIG. 1G), for example by a Siconi etch. During each of the dry etch and the wet etch, the thickness of material 109 may be reduced, but the width remains the same due to the slow etch rate. Thus, unlike with HDP oxide, which ends being the width of the STI region 103, the SDB material 109 overhangs the edges of the STI region 103.

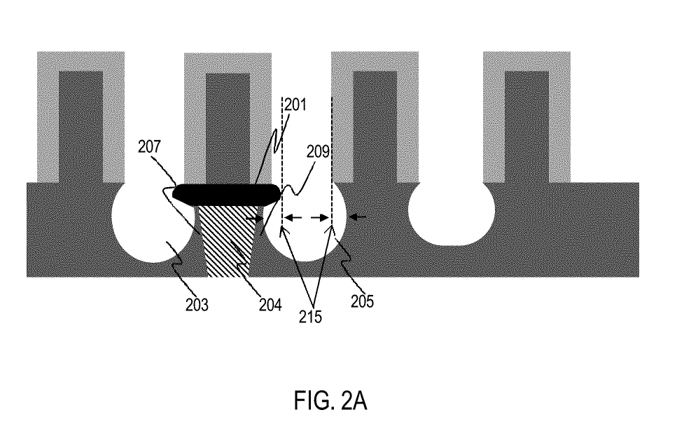

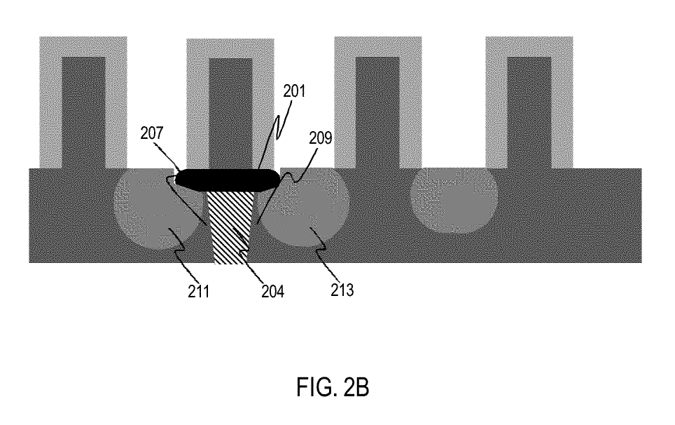

FIG. 2A through 2B schematically illustrate SDB material preventing cavities from touching the STI, in accordance with an exemplary embodiment. In current practice, the continued cavity etching to achieve optimized proximity results in the cavity touching the STI oxide and leaving no Si on the STI sidewalls. In FIG. 2A, the SDB material 201 overhangs the sidewalls of STI region 204, thereby protecting the Si on the sidewalls and leaving a layer of Si 207 and 209 on the STI sidewalls as cavities 203 and 205 are formed, respectively. Adverting to FIG. 2B, eSiGe/eSiP 211 and 213 is epitaxially grown in the cavities 203 and 205. The Si 207 and 209 remaining on the t-shaped SDB STI sidewalls provides a seed layer for the eSiGe/eSiP, which results in minimum facet EPI.

The embodiments of the present disclosure can achieve several technical effects, such as, improving the junction EPI facet issue to boost device performance. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated finFET semiconductor devices, particularly for the 14 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. The method comprising:
providing a shallow trench isolation (STI) region in a silicon (Si) substrate;
forming a hardmask over the STI region and the Si substrate;
forming a cavity through the hardmask over the STI region, the cavity having a width greater than a width of the STI region;
depositing a single diffusion break (SDB) oxide material in the cavity with an etch rate lower than HDP oxide to form a t-shape SDB STI structure; and
removing the hardmask.

2. The method according to claim 1, comprising forming the SDB material of silicon dioxide (SiO₂) modified with nitrogen (N).

3. The method according to claim 2, wherein the SDB material has an etch rate ratio between etch rates of pure oxide and silicon nitride (SiN).

4. The method according to claim 2, comprising modifying the SiO₂is with 10 to 40% of N.

5. The method according to claim 1, comprising forming the SDB material of silicon dioxide (SiO₂) modified with carbon (C).

6. The method according to claim 5, wherein the SDB material has an etch rate ratio between etch rates of pure oxide and silicon carbide (SiC).

7. The method according to claim 5, comprising modifying the SiO₂with 1 to 15% of C.

8. The method according to claim 1, comprising forming the SDB material of pure nitride.

9. The method according to claim 1, further comprising:
providing trenches filled with STI material in the Si substrate perpendicular to the STI region;
recessing the STI material to form Si FINs subsequent to removing the hardmask,
wherein an SDB layer width is greater than the STI region width subsequent to recessing the STI material.

10. The method according to claim 9, wherein the SDB layer width is 35 to 90 nanometers (nm).

11. The method according to claim 1, further comprising:
forming a cavity in the Si substrate adjacent to each side of the STI; and
epitaxially growing a silicon germanium (eSiGe) or silicon phosphorus (eSiP) in the cavities.

12. The method according to claim 11, wherein the SDB layer prevents the cavity from touching the STI.

13. The device comprising:
a silicon (Si) substrate with FINs;
shallow trench isolation (STI) material in the substrate between the FINs;
an STI region in a FIN and extending into the underlaying Si substrate;
a single diffusion break (SDB) oxide material with an etch rate lower than HDP oxide over the STI forming a t-shape SDB STI structure; and
source/drain (S/D) regions on opposite sides of the STI region, the S/D being separated from the STI region with silicon.

14. The device according to claim 13, wherein the SDB layer has a width of 35 to 90 nanometers (nm).

15. The device according to claim 13, wherein the SDB comprises silicon dioxide (SiO₂) modified with nitrogen (N) and the SDB has an etch rate ratio between etch rates of pure oxide and silicon nitride (SiN).

16. The device according to claim 15, wherein the SiO₂is modified with 10 to 40% of N.

17. The device according to claim 13, wherein the SDB comprises silicon dioxide (SiO₂) modified with carbon (C) and the SDB material has an etch rate ratio between etch rates of pure oxide and silicon carbide (SiC).

18. The device according to claim 17, wherein the SiO₂is modified with 1 to 15% of C.

19. The device according to claim 13, wherein the SDB material comprises pure nitride.

20. The method comprising:
providing a shallow trench isolation (STI) region in a silicon (Si) substrate;
depositing a hardmask silicon nitride (HM SiN) material over the STI region and the Si substrate to form a hardmask;
forming a photoresist on an upper surface of the hardmask;
removing a center portion of the hardmask to form an opening;
removing the photoresist;
etching the STI region and the Si substrate through the opening to form a cavity over the STI region, the cavity having a width greater than a width of the STI region;
depositing a single diffusion break (SDB) material comprising silicon dioxide (SiO₂) modified with nitrogen (N) or carbon (C) or pure nitride, the SDP material in the cavity;
planarizing the SDB material down to the hardmask to form a t-shape SDB STI structure; and
removing the hardmask;
providing trenches filled with STI material in the Si substrate perpendicular to the STI region;
recessing the STI material to form Si FINs subsequent to removing the hardmask,
wherein an SDB layer width is greater than the STI region width subsequent to recessing the STI material.
